(19) United States
(12) Patent Application Publication
(10) Pub. No.: US 2018/0336829 A1
(43) Pub. Date: Nov. 22, 2018

(54) ARRAY SUBSTRATE AND DISPLAY PANEL

(71) Applicant: Wuhan China Star Optoelectronics Technology Co., Ltd., Wuhan, Hubei (CN)

(72) Inventor: Haibo PENG, Shenzhen, Guangdong (CN)

(73) Assignee: Wuhan China Star Optoelectronics Technology Co., Ltd., Wuhan, Hubei (CN)

(21) Appl. No.: 15/328,458

(22) PCT Filed: Dec. 30, 2016
(86) PCT No.: PCT/CN2016/113763

§ 371 Date: Jan. 23, 2017

(30) Foreign Application Priority Data
Dec. 29, 2016 (CN) 201611247165.4

(51) Int. Cl. G09G 3/34; H01L 33/00

(52) U.S. Cl. CPC G09G 3/34; H01L 33/00

(57) ABSTRACT

An array substrate is disclosed, including a pixel electrode disposed on the array substrate, wherein, the pixel electrode includes a first pixel sub-electrode and a second pixel sub-electrode arranged at upper portion and lower portion of the pixel electrode; the first pixel sub-electrode includes at least two first main trunk portions disposed in parallel and aslant, and a first bending portion disposed at a terminal of each first main trunk portion away from the second pixel sub-electrode; the second pixel sub-electrode includes at least three second main trunk portions disposed in parallel and disposed aslant, and a in second bending portion disposed at a terminal of each second main trunk portion away from the first pixel sub-electrode. A display panel is also disclosed, including a CF substrate and an array substrate disposed oppositely to the CF substrate. Transmittance of the pixel electrode is increased in order to decrease the power consumption.

### BACKGROUND OF THE INVENTION

### 1. Field of the Invention

The present invention relates to a liquid crystal display technology, and more particularly to an array substrate and a display panel.

### 2. Description of Related Art

Along with the improvement of the resolution of mobile phone product, aperture ratio of the panel is lower and lower. In order to achieve a brightness level of a display panel for a normal visual requirement, usually, the number of LED is increased. However, in one aspect, the cost is increased, and in another aspect, the power consumption of the display panel is also increased so that an operation time of a mobile device such as a mobile phone is reduced after a single charging. Accordingly, how to increase the transmittance of the panel, decrease the product power consumption has become a direction of efforts for industry.

### SUMMARY OF THE INVENTION

In order to overcome the shortcomings of the conventional art, the present invention provides an array substrate and a display panel in order to increase the transmittance.

The present invention provides an array substrate including a pixel electrode disposed on the array substrate, wherein, the pixel electrode includes a first pixel sub-electrode and a second pixel sub-electrode arranged at an upper portion and a lower portion of the pixel electrode; the first pixel sub-electrode includes at least two first main trunk portions disposed in parallel and disposed aslant, and a first bending portion disposed at a terminal of each first main trunk portion away from the second pixel sub-electrode; the second pixel sub-electrode includes at least three second main trunk portions disposed in parallel and disposed aslant, and a second bending portion disposed at a terminal of each second main trunk portion away from the first pixel sub-electrode.

Furthermore, a slanting direction of the first main trunk portion and a slanting direction of the second main trunk portion are opposite.

Furthermore, a spacing is provided between the first pixel sub-electrode and the second pixel sub-electrode; terminals of the two first main trunk portions relative to the second pixel sub-electrode are connected with each other through a first connection portion, and terminals of the second main trunk portions relative to the first pixel sub-electrode are connected with each other through a second connection portion; the first connection portion and the second connection portion are disposed in parallel.

Furthermore, terminals of two outermost first main trunk portions in the first pixel sub-electrode relative to the second pixel sub-electrode are connected to terminals of two outermost second main trunk portions in the second pixel sub-electrode relative to the first pixel sub-electrode; the first pixel sub-electrode and the second pixel sub-electrode are connected with each other through a third connection portion.

Furthermore, the third connection portion is connected to connection locations of the two outermost first main trunk portions and the two outermost second main trunk portions and a terminal of the second main trunk portion disposed at a middle of the second pixel sub-electrode relative to the first pixel sub-electrode.

Furthermore, the first pixel sub-electrode is disposed at the upper portion of the pixel electrode and the second pixel sub-electrode is disposed at the lower portion of the pixel electrode; or the second pixel sub-electrode is disposed at the upper portion of the pixel electrode and the first pixel sub-electrode is disposed at the lower portion of the pixel electrode.

Furthermore, the first pixel sub-electrode is disposed at the upper portion of the pixel electrode and the second pixel sub-electrode is disposed at the lower portion of the pixel electrode; or the second pixel sub-electrode is disposed at the upper portion of the pixel electrode and the first pixel sub-electrode is disposed at the lower portion of the pixel electrode.

Furthermore, locations of the first pixel sub-electrodes in adjacent two pixel electrodes are opposite.

Furthermore, locations of the first pixel sub-electrodes in adjacent two pixel electrodes are opposite.

The present further provides a display panel, including a CF substrate, and an array substrate described above, wherein, the array substrate is disposed oppositely to the CF substrate.

Comparing to the conventional art, through two pixel sub-electrodes disposed upper and lower, one of the two pixel sub-electrodes is provided with two main trunk portions, the other of the two pixel sub-electrodes is provided with three main trunk portions. Adopting a connected or a separated arrangement so that the transmittance of the pixel electrode is increased in order to increase the entire transmittance, and reduce the power consumption.

### BRIEF DESCRIPTION OF THE DRAWINGS

FIG. 1 is a schematic diagram of a structure according to a first embodiment of the present invention;

FIG. 2 is a schematic diagram of a structure according to a second embodiment of the present invention;

FIG. 3 is a schematic diagram of a structure according to a third embodiment of the present invention; and

FIG. 4 is a schematic diagram of an arrangement way according to the present invention.

### DETAILED DESCRIPTION OF THE PREFERRED EMBODIMENT

The following content will combine with the figures and the embodiments for illustrating the present invention in detail.

An array substrate of the present invention includes a pixel electrode 1 disposed on the array substrate. Because the improvement of the present invention is at the pixel electrode 1 itself, the following content only describes the pixel electrode 1 in detail, and the pixel electrode 1 in the present invention is a slit electrode.

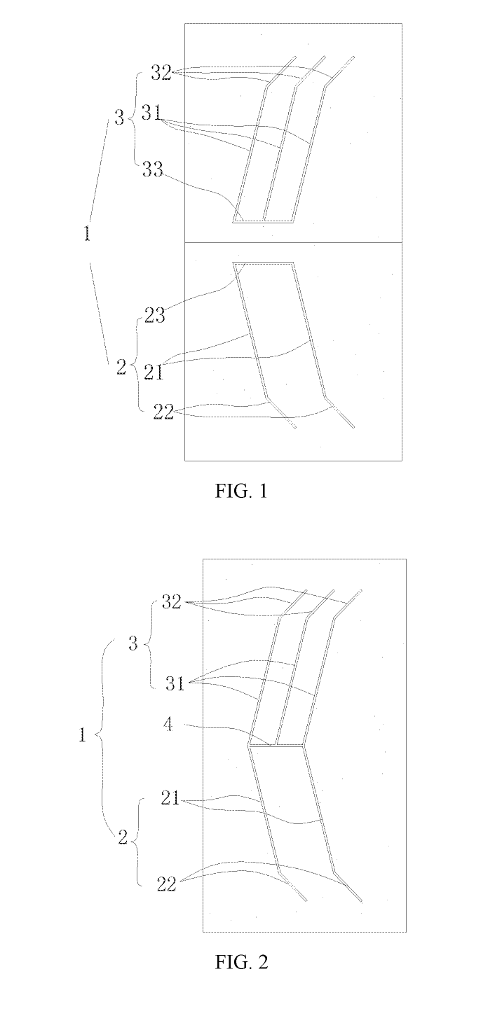

As shown in FIG. 1, which is a schematic diagram of a structure according to a first embodiment of the present invention. An array substrate, including a pixel electrode 1 disposed on the array substrate. The pixel electrode includes a first pixel sub-electrode 2 and a second pixel sub-electrode 3 arranged at an upper portion and a lower portion of the pixel electrode. Wherein, the first pixel sub-electrode 2 includes two first main trunk portions 21 disposed in parallel and disposed aslant, a first bending portion 22 disposed at a terminal of each first main trunk portion 21 away from the second pixel sub-electrode 3.

The second pixel sub-electrode 3 includes three second main trunk portions 31 disposed in parallel and disposed aslant, and a second bending portion 32 disposed at a terminal of each second main trunk portion 31 away from the first pixel sub-electrode 2. Intervals among the three second main trunk portions 31 are equal. A slanting direction of the first main trunk portion 21 and a slanting direction of the second main trunk portion 31 are opposite. A spacing is provided between the first pixel sub-electrode 2 and the second pixel sub-electrode 3. Terminals of the two first main trunk portions 21 relative to the second pixel sub-electrode 3 are connected with each other through a first connection portion 23. Terminals of the second main trunk portions 31 relative to the first pixel sub-electrode 2 are connected with each other through a second connection portion 33. The first connection portion 23 and the second connection portion 33 are disposed in parallel. Finally, a slit electrode is formed. In the present embodiment, except the second main trunk portion 21 disposed at the middle of the second pixel sub-electrode 3, external contours of the first pixel sub-electrode 2 and the second pixel sub-electrode 3 are symmetrical. The first bending portions 22 and the second bending portions 32 are bent toward a same side, that is, a right side in the figures such that an included angle between the bending portion and the main trunk portion is less than 180 degrees.

In the first embodiment, the location of the first pixel sub-electrode 2 is at the upper portion or the lower portion of the pixel electrode 1. Correspondingly, the location of the second pixel sub-electrode 3 is at the lower portion or the upper portion of the pixel electrode 1.

In the first embodiment, the transmittance is 4.3%, and a driving voltage is 4.35V. Comparing to the pixel electrode only providing with the first pixel sub-electrode 2 (transmittance is 4%, driving voltage is 4V) disposed symmetrically at the upper portion and the lower portion of the pixel electrode, or symmetrically disposing the second pixel sub-electrode 3 (transmittance is 4.5%, driving voltage is 4.8V), the transmittance is still increased greatly, and the driving voltage is also improved at the same time.

As shown in FIG. 2, which is an array substrate of a second embodiment of the present invention. An array substrate including a pixel electrode 1 disposed on the array substrate. The pixel electrode includes a first pixel sub-electrode 2 and a second pixel sub-electrode 3 arranged at an upper portion and a lower portion of the pixel electrode. The first pixel sub-electrode 2 is disposed at the lower portion of the pixel electrode 1, and the second pixel sub-electrode 3 is disposed at the upper portion of the pixel electrode 1.

Wherein, the first pixel sub-electrode 2 includes two first main trunk portions 21 disposed in parallel and disposed aslant, a first bending portion 22 disposed at a terminal of each first main trunk portion 21 away from the second pixel sub-electrode 3.

The second pixel sub-electrode 3 includes three second main trunk portions 31 disposed in parallel and disposed aslant, and a second bending portion 32 disposed at a terminal of each second main trunk portion 31 away from the first pixel sub-electrode 2. Intervals among the three second main trunk portions 31 are equal. A slanting direction of the first main trunk portion 21 and a slanting direction of the second main trunk portion 31 are opposite.

Terminals of two outermost first main trunk portions 21 in the first pixel sub-electrode 2 relative to the second pixel sub-electrode 3 are connected to terminals of two outermost second main trunk portions 31 in the second pixel sub-electrode 3 relative to the first pixel sub-electrode 2 so as to form a V-shape rotated 90 degrees clockwise. The first pixel sub-electrode 2 and the second pixel sub-electrode 3 are connected with each other through a third connection portion 4. The first bending portions 22 and the second bending portions 32 are bent toward a same side, that is, a right side in the figures such that an included angle between the bending portion and the main trunk portion is less than 180 degrees. Finally, a slit electrode is formed.

Specifically, the third connection portion 4 is connected to connection locations of the two outermost first main trunk portions 21 and the two outermost second main trunk portions 31 and a terminal of the second main trunk portion 31 disposed at middle of the second pixel sub-electrode 3 relative to the first pixel sub-electrode 2.

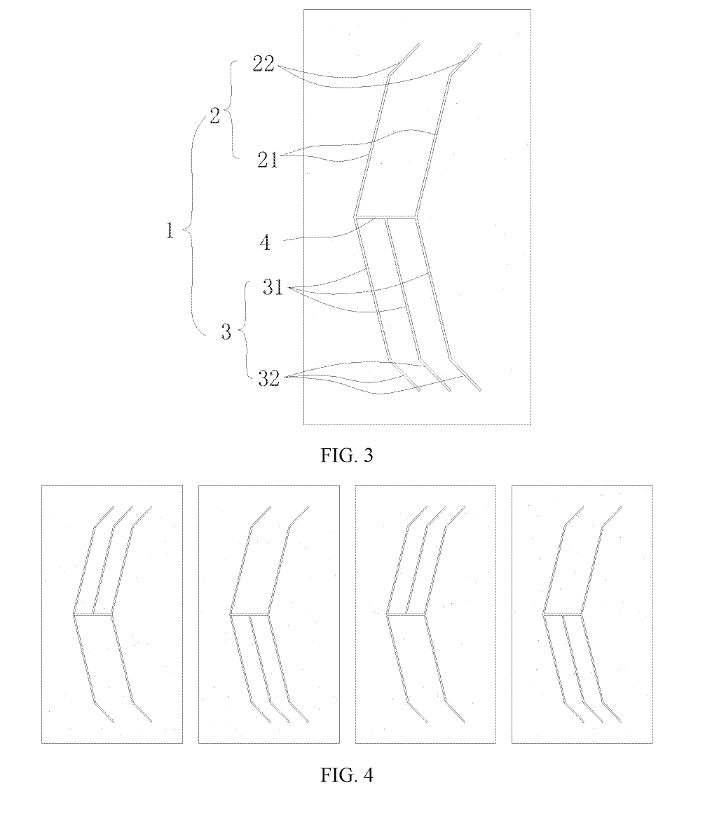

As shown in FIG. 3, the difference between the third embodiment and the second embodiment is that the second pixel sub-electrode 3 is disposed at a lower portion of the pixel electrode 1, and the second pixel sub-electrode 2 is disposed at an upper portion of the pixel electrode 1.

As shown in FIG. 4, which is an arrangement way of the present invention. In an actual application, in the entire pixel electrode, different transmittances will occur. In order to avoid generating bright and dark stripes, two second pixel sub-electrodes 3 in two adjacent pixel electrodes are arranged oppositely. As shown in FIG. 4, the second pixel sub-electrode 3 at a left-side pixel electrode is disposed at an upper portion of the left-side pixel electrode (the second embodiment), and the second pixel sub-electrode 3 at a right-side pixel electrode and adjacent to the left-side pixel electrode is disposed at a lower portion of the pixel electrode 1 (the third embodiment). That is, in an arrangement of pixel electrodes, the second pixel sub-electrodes 3 in two adjacent pixel electrodes cannot be located at a same side (e.g. all are disposed at the upper portion or at the lower portion).

The present invention also discloses a display panel, including a color filter (CF) substrate and an array substrate of any one of the above embodiments. The array substrate and the CF substrate are disposed oppositely, and a liquid crystal layer is disposed between the array substrate and the CF substrate.

The present invention is suitable for a display panel adopting FFS technology.

The above content combines the embodiments to describe the present invention, however, the implement of the present invention is not limited. Within the spirit and scope of present invention, the person in this technology field can perform various modifications and variations. The modifications and variations are still covered by the claims in the present invention.

What is claimed is:

1. An array substrate including a pixel electrode disposed on the array substrate, wherein, the pixel electrode includes a first pixel sub-electrode and a second pixel sub-electrode arranged at an upper portion and a lower portion of the pixel electrode; the first pixel sub-electrode includes at least two first main trunk portions disposed in parallel and disposed aslant, and a first bending portion disposed at a terminal of each first main trunk portion away from the second pixel sub-electrode; the second pixel sub-electrode includes at least three second main trunk portions disposed in parallel and disposed aslant, and a second bending portion disposed at a terminal of each second main trunk portion away from the first pixel sub-electrode.

2. The array substrate according to claim 1, wherein, a slanting direction of the first main trunk portion and a slanting direction of the second main trunk portion are opposite.

3. The array substrate according to claim 2, wherein, a spacing is provided between the first pixel sub-electrode and the second pixel sub-electrode; terminals of the two first main trunk portions relative to the second pixel sub-electrode are connected with each other through a first connection portion, and terminals of the second main trunk portions relative to the first pixel sub-electrode are connected with each other through a second connection portion; the first connection portion and the second connection portion are disposed in parallel.

4. The array substrate according to claim 2, wherein, terminals of two outermost first main trunk portions in the first pixel sub-electrode relative to the second pixel sub-electrode are connected to terminals of two outermost second main trunk portions in the second pixel sub-electrode relative to the first pixel sub-electrode; the first pixel sub-electrode and the second pixel sub-electrode are connected with each other through a third connection portion.

5. The array substrate according to claim 4, wherein, the third connection portion is connected to connection locations of the two outermost first main trunk portions and the two outermost second main trunk portions and a terminal of the second main trunk portion disposed at a middle of the second pixel sub-electrode relative to the first pixel sub-electrode.

6. The array substrate according to claim 3, wherein, the first pixel sub-electrode is disposed at the upper portion of the pixel electrode and the second pixel sub-electrode is disposed at the lower portion of the pixel electrode; or the second pixel sub-electrode is disposed at the upper portion of the pixel electrode and the first pixel sub-electrode is disposed at the lower portion of the pixel electrode.

7. The array substrate according to claim 5, wherein, the first pixel sub-electrode is disposed at the upper portion of the pixel electrode and the second pixel sub-electrode is disposed at the lower portion of the pixel electrode; or the second pixel sub-electrode is disposed at the upper portion of the pixel electrode and the first pixel sub-electrode is disposed at the lower portion of the pixel electrode.

8. The array substrate according to claim 6, wherein, locations of the first pixel sub-electrodes in adjacent two pixel electrodes are opposite.

9. The array substrate according to claim 7, wherein, locations of the first pixel sub-electrodes in adjacent two pixel electrodes are opposite.

10. A display panel comprising a CF substrate, wherein, the display panel further comprises an array substrate disposed oppositely to the CF substrate, the array substrate including a pixel electrode disposed on the array substrate, wherein, the pixel electrode includes a first pixel sub-electrode and a second pixel sub-electrode arranged at an upper portion and a lower portion of the pixel electrode; the first pixel sub-electrode includes at least two first main trunk portions disposed in parallel and disposed aslant, and a first bending portion disposed at a terminal of each first main trunk portion away from the second pixel sub-electrode; the second pixel sub-electrode includes at least three second main trunk portions disposed in parallel and disposed aslant, and a second bending portion disposed at a terminal of each second main trunk portion away from the first pixel sub-electrode.

11. The display panel according to claim 10, wherein, a slanting direction of the first main trunk portion and a slanting direction of the second main trunk portion are opposite.

12. The display panel according to claim 11, wherein, a spacing is provided between the first pixel sub-electrode and the second pixel sub-electrode; terminals of the two first main trunk portions relative to the second pixel sub-electrode are connected with each other through a first connection portion, and terminals of the second main trunk portions relative to the first pixel sub-electrode are connected with each other through a second connection portion; the first connection portion and the second connection portion are disposed in parallel.

13. The display panel according to claim 11, wherein, terminals of two outermost first main trunk portions in the first pixel sub-electrode relative to the second pixel sub-electrode are connected to terminals of two outermost second main trunk portions in the second pixel sub-electrode relative to the first pixel sub-electrode; the first pixel sub-electrode and the second pixel sub-electrode are connected with each other through a third connection portion.

14. The display panel according to claim 13, wherein, the third connection portion is connected to connection locations of the two outermost first main trunk portions and the two outermost second main trunk portions and a terminal of the second main trunk portion disposed at a middle of the second pixel sub-electrode relative to the first pixel sub-electrode.

15. The display panel according to claim 12, wherein, the first pixel sub-electrode is disposed at the upper portion of the pixel electrode and the second pixel sub-electrode is disposed at the lower portion of the pixel electrode; or the second pixel sub-electrode is disposed at the upper portion of the pixel electrode and the first pixel sub-electrode is disposed at the lower portion of the pixel electrode.

16. The display panel according to claim 14, wherein, the first pixel sub-electrode is disposed at the upper portion of the pixel electrode and the second pixel sub-electrode is disposed at the lower portion of the pixel electrode; or the second pixel sub-electrode is disposed at the upper portion of the pixel electrode and the first pixel sub-electrode is disposed at the lower portion of the pixel electrode.

17. The display panel according to claim 15, wherein, locations of the first pixel sub-electrodes in adjacent two pixel electrodes are opposite.

18. The display panel according to claim 16, wherein, locations of the first pixel sub-electrodes in adjacent two pixel electrodes are opposite.
